(19) United States
(12) Patent Application Publication
(10) Pub. No.: US 2026/0029468 A1
(43) Pub. Date: Jan. 29, 2026

(54) DIAGNOSTICS SELF-TESTS FOR POWER TOOLS

(71) Applicant: Milwaukee Electric Tool Corporation, Brookfield, WI (US)

(72) Inventors: Timothy J. Radtke, New Berlin, WI (US); Luke J. Skinner, West Bend, WI (US)

(21) Appl. No.: 19/277,894

(22) Filed: Jul. 23, 2025

Related U.S. Application Data
(60) Provisional application No. 63/675,084, filed on Jul. 24, 2024.

(51) Int. Cl. G01R 31/34; H02P 23/00

(52) U.S. Cl. CPC G01R 31/343; H02P 23/00

(57) ABSTRACT

A power tool device and method are provided in which a power tool device includes a device housing, a power tool battery pack interface coupled to the device housing, and an electronic controller. The electronic controller includes a memory storing firmware and a processor configured to execute the firmware to cause the electronic controller to: receive a request from an external device to perform a self-test; in response to the request, perform the self-test; record results corresponding to the self-test; and export the results to the external device. The power tool device may further include a diagnostic integrated circuit that includes a separate processing circuit, a diagnostic sensor, and an external communication interface. The diagnostic integrated circuit receives power from an external device, performs a diagnostic test of the electronic controller, and transmits a test result of the diagnostic test of the electronic controller to the external device.

### RELATED APPLICATIONS

This application claims priority to U.S. Provisional Application No. 63/675,084, filed on Jul. 24, 2024, which is hereby incorporated by reference in its entirety.

### BACKGROUND

Power tools allow operators to implement various functionalities. To implement said various functionalities, the power tools may include various electrical components, each responsible for performing one or more functionalities.

### SUMMARY

Some embodiments of the disclosure provide a method of performing tool diagnostics. The method includes receiving, by an electronic controller of a power tool device, a request from an external device to perform a self-test; in response to the request, executing, by the electronic controller, firmware of the power tool device to perform the self-test; recording, by the electronic controller executing the firmware, results corresponding to the self-test; and exporting, by the electronic controller, the results to the external device.

Some embodiments of the disclosure provide a power tool device. The power tool device includes: a device housing; a power tool battery pack interface coupled to the device housing; an electronic controller including a memory storing firmware and a processor configured to execute the firmware to cause the electronic controller to: receive a request from an external device to perform a self-test; in response to the request, perform the self-test; record results corresponding to the self-test; and export the results to the external device.

In some examples of the system or method, the request from the external device is received by the electronic controller via terminals of a power tool battery pack interface of the power tool device.

In some examples, the system or method includes requesting, via the external device, an action be performed by a user while the self-test is performed.

In some examples, of the system or method, the action comprises the user pulling a trigger of the power tool device.

In some examples of the system or method, the action comprises the user confirming an illumination of a light emitting diode (LED), and wherein performing the self-test comprises illuminating the LED.

In some examples of the system or method, the self-test comprises a plurality of diagnostic tests of one or more components of the power tool device, the plurality of diagnostic tests including a diagnostic test of at least one selected from a group of: a radio module, a transistor, a sensor, or a storage module.

In some examples, the system or method includes receiving, by a diagnostic integrated circuit housed within the power tool device, power from the external device, wherein the diagnostic integrated circuit includes a processing circuit separate from a processor of the electronic controller, a diagnostic sensor, and an external communication interface; performing, by the diagnostic integrated circuit, a diagnostic test of the electronic controller; and transmitting, by the diagnostic integrated circuit via the external communication interface, a test result of the diagnostic test of the electronic controller to the external device.

In some examples of the system or method, the request from the external device is received by the electronic controller via the power tool battery pack interface and the results exported to the external device are transmitted by the electronic controller via the power tool battery pack interface.

In some examples of the system or method, the power tool device further comprising: a motor supported by the device housing and coupled to the electronic controller; and a trigger coupled to the electronic controller, wherein the electronic controller is further configured to drive the motor in response to actuation of the trigger.

In some examples, the system or method includes a diagnostic integrated circuit housed by the device housing and comprising: a processing circuit separate from the processor of the electronic controller, a diagnostic sensor, and an external communication interface, wherein the diagnostic integrated circuit is configured to: receive power from the external device; perform, by the processing circuit, a diagnostic test of the electronic controller; and transmit, by the processing circuit via the external communication interface, a test result of the diagnostic test of the electronic controller to the external device.

In some examples, the system or method includes a motor supported by the device housing; and a switching network coupled to the electronic controller, wherein the electronic controller is configured to control the switching network to drive the motor, wherein the diagnostic integrated circuit further comprises: a service switching interface coupling the processing circuit to the switching network, a power sensor configured to detect power at a power supply for the electronic controller, a plurality of diagnostic sensors, and a power input interface configured to receive the power from the external device.

In some examples of the system or method, performing the self-test comprises illuminating a light emitting diode (LED).

In some examples of the system or method, the power tool device is a motorized power tool is a drill-driver, an impact driver, a crimper, or a saw.

Some embodiments of the disclosure provide a power tool device. The power tool device includes: a device housing; a power tool battery pack interface coupled to the device housing; an electronic controller including a memory storing firmware and a processor configured to execute the firmware to cause the electronic controller to operate electronics of the power tool device. The power tool device further includes a diagnostic integrated circuit housed by the device housing and comprising: a processing circuit separate from the processor of the electronic controller, a diagnostic sensor, and an external communication interface, wherein the diagnostic integrated circuit is configured to: receive power from an external device; perform, by the processing circuit, a diagnostic test of the electronic controller; and transmit, by the processing circuit via the external communication interface, a test result of the diagnostic test of the electronic controller to the external device.

Some embodiments of the disclosure provide a method of performing tool diagnostics. The method includes operating, by an electronic controller of a power tool device, electronics of the power tool device; receiving, by a diagnostic integrated circuit of the power tool device, power from an external device, wherein the diagnostic integrated circuit comprises a processing circuit separate from a processor of the electronic controller, a diagnostic sensor, and an external communication interface; performing, by the processing circuit, a diagnostic test of the electronic controller; and transmitting, by the processing circuit via the external communication interface, a test result of the diagnostic test of the electronic controller to the external device.

In some examples, the system or method may include controlling, by the electronic controller, a switching network to apply power from a power tool battery pack to a motor to drive the motor, wherein the diagnostic integrated circuit is offline and unpowered by the power tool battery pack when the switching network is controlled to apply power from the power tool battery pack to the motor.

In some examples, the system or method may include controlling, by the electronic controller, a switching network coupled to the electronic controller to drive a motor, wherein the diagnostic integrated circuit comprises: a service switching interface coupling the processing circuit to the switching network, a power sensor configured to detect power at a power supply for the electronic controller, a plurality of diagnostic sensors, and a power input interface configured to receive the power from the external device.

In some examples, the system or method may include wherein the plurality of diagnostic sensors comprises at least one of: a power regulation sensor, a pressure sensor, an inductive position sensor, or an inertial measurement unit sensor.

In some examples of the system or method, the power tool device is a motorized power tool is a drill-driver, an impact driver, a crimper, or a saw.

### BRIEF DESCRIPTION OF THE DRAWINGS

The accompanying drawings, which are incorporated in and form a part of this specification, illustrate embodiments of the disclosure and, together with the description, serve to explain principles of the embodiments:

FIG. 1 shows a perspective view of a power tool, according to some examples.

FIG. 2 is a schematic illustration of a communication system, according to some examples.

FIG. 3A shows a block diagram of a power tool control system, according to some examples.

FIG. 3B shows a block diagram of a user device, according to some examples.

FIG. 4 shows a flowchart of a process for performing tool diagnostics, according to some examples.

FIG. 5 a block diagram of a tool control system and a diagnostic system, according to some examples.

FIG. 6 shows another flowchart of a process for performing tool diagnostics, according to some examples.

### DETAILED DESCRIPTION

As described above, power tools may include various electrical components, each responsible for performing one or more functionalities. By collecting information regarding the performance of various electronic components within a power tool, failures can be classified, future failures can be predicted, and maintenance can be scheduled to maintain or improve the performance of the electronic components.

Power tool devices may experience errors, faults, or malfunctions over time while in operation in the field. In part because of the complexity of modern power tool devices, determining causes of these errors, faults, or malfunctions of a power tool device may be challenging. Features of the systems, power tool devices, and processes described herein enable a service technician to more quickly and accurately diagnosis an error, fault, or malfunction of a power tool device in the field. For example, rather than simply identifying that a control system or corresponding circuit board is malfunctioning, using the systems, devices, and processes described herein, a service technician can identify particular electronics or features of the power tool device, control system, or corresponding circuit board that may be experiencing an issue. This more granular information may be used, for example, for improving future designs, fixing a currently malfunctioning power tool device, and/or evaluating warranty claims.

Some embodiments described herein provide improved systems and methods to perform tool diagnostics. For example, some embodiments of the disclosure provide a power tool device that may perform self-tests requested by a user device. For example, a controller within a power tool may receive a request from the user device for a specific self-test to be executed. The controller may then execute firmware to perform the requested self-test and provide the results to the user device.

Further, some embodiments of the disclosure provide a diagnostic system in a tool housing of a power tool device that is independent and isolated from a (main) tool control system of the power tool device. The diagnostic system may provide additional diagnostic testing capabilities to supplement self-tests of the tool control system, including performing diagnostics tests of a malfunctioning controller of the main tool control system, and may be selectively powered via an independent power source (thus, not impacting power tool battery life).

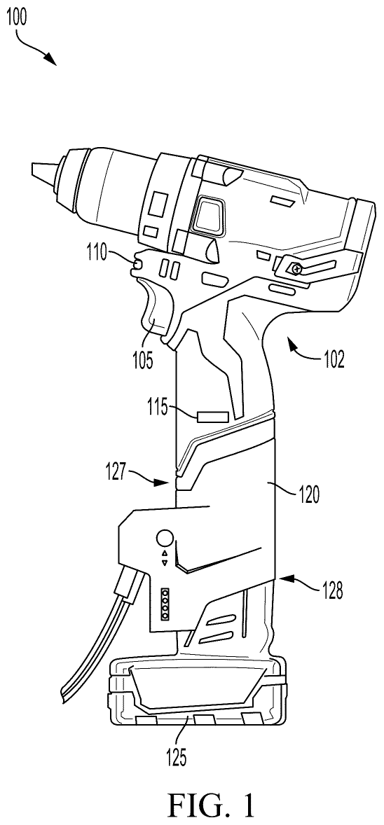

FIG. 1 illustrates a perspective view of a power tool device 100. In FIG. 1, the power tool device 100 is illustrated as a motorized power tool that includes a main body 102, a trigger 105, a light emitting diode (LED) 110, a data port 115, an adapter 120, a battery pack 125, and a battery pack interface 127. As illustrated, the battery pack interface 127 receives and is electro-mechanically coupled to the adapter 120, which itself has a further battery pack interface 128 that receives and is electro-mechanically coupled to the battery pack 125. When the adapter 120 is not coupled to the battery pack interface 127, the battery pack 125 may be electro-mechanically coupled to the battery pack interface 127. Thus, the battery pack 125 may couple to main body 102 directly or may couple to the main body 102 indirectly via the adapter 120. In some examples, the data port 115 may include a USB port, a micro-USB port, an RS-232 port, a proprietary port, another suitable power and/or data port, or a combination thereof. In some examples of the power tool device 100, the battery pack 125 is not present, for example, when an external device is connected to the main body 102 and provides power via the adapter 120 or the data port 115. In some examples, the power tool device 100 includes both the data port 115 and the adapter 120 (as illustrated), while in other examples, the power tool device includes either the data port 115 or the adapter 120.

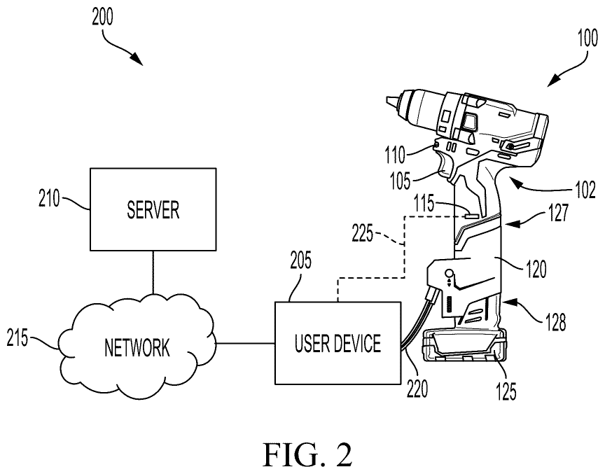

In general, the power tool adapter 120, the data port 115, or both, create a communication path between the power tool device 100 and an external device (see, e.g., user device 205 of FIG. 2). In some examples, the power tool adapter 120 is coupled to an external device and the power tool device 100 is communicatively coupled to the external device via the power tool adapter 120. In some examples, the data port 115 is coupled to an external device and the power tool device 100 is communicatively coupled to the external device via the data port 115.

As explained further below, the power tool device 100 may couple to the external device (see, e.g., user device 205 of FIG. 2), via the adapter 120 and/or the data port 115, to export information from the power tool device 100 and/or to import information into the power tool device 100. The power tool device 100, for example, may obtain and export tool diagnostic data, self-test results, mode information, drive device information, and the like to the external device. The power tool device 100 may also import instructions from the external device such as, for example, instructions to cause a self-test or diagnostic test.

As illustrated, the power tool device 100 is a motorized power tool. That is, the power tool device 100 includes a motor within the main body 102 and that is selectively driven using power from the power tool battery pack 125. In some examples, the power tool device 100 is another type of motorized power tool. Each type of motorized power tool can include a moveable component and an actuator (e.g., a motor) that can move (e.g., translate, rotate, reciprocate, oscillate, etc.) the moveable component to implement a functionality on a workpiece. For example, a motorized power tool can be a drill-driver (e.g., including chuck for receiving drill bits and driving bits), an impact driver, a crimper, a cutter, a reciprocating saw, a circular saw, a pump, a fan, or the like. In other examples, the power tool device 100 is a nonmotorized power tool. Each non-motorized power tool can lack a motor, a moveable component, etc., and thus can lack the ability to implement a functionality on a workpiece. For example, a non-motorized power tool can be a radio, a light, a speaker, a power supply (e.g., a portable power supply), or the like. Thus, although shown as a particular type of power tool in FIG. 1, the power tool device 100 can be implemented as various types of power tools, including as a motorized power tool or a non-motorized power tool. As used herein, a “power tool device” may include a power tool (whether motorized or non-motorized), a power tool battery pack, a power tool battery pack charger, or a combination thereof.

FIG. 2 illustrates a schematic diagram of the communication system 200 according to some configurations. As illustrated in FIG. 2, the communication system 200 can include the power tool device 100, a user device 205, a server 210, and a network 215. In the example of FIG. 2, the power tool adapter 120 is physically (or electro-mechanically) coupled to the power tool device 100 and the power tool battery pack 125. The power tool adapter 120 is further connected to the user device 205 via a communication connection 220. Thus, the power tool device 100 is illustrated as communicatively coupled to the user device 205 via the adapter 120 and communication connection 220. However, additionally or alternatively, the power tool device 100 may be communicatively coupled to the user device 205 via the data port 115 and a communication connection 225. The communication connections 220 and 225 may be a wired connection or cable such as, for example, a USB cable, a micro-USB cable, an RS-232 cable, a proprietary cable, or the like.

As noted above with respect to FIG. 1, although the power tool device 100 is illustrated as a particular type of motorized power tool (a hammer drill-driver), in other examples, the power tool device is another type of power tool, a power tool battery pack, or a power tool charger, which may similarly be coupled to a user device 205 via a battery interface and the adapter 120 or via a data port 115 of the power tool device.

The user device 205 may be, for example, a laptop computer, a tablet computer, a smartphone, a cellphone, or another electronic device capable of communicating with the power tool device 100 to provide a user interface via the adapter 120 and/or the data port 115. In some examples, the user device 205 includes a communication interface that is compatible with the power tool adapter 120. In some examples, the user device 205 includes a communication interface that is compatible with data port 115. In particular, the communication interface of the user device 205 may include connections ports for communication via a USB port, a micro-USB port, an RS-232 port, another suitable power and/or data port, a wireless communication module (e.g., a Bluetooth® module), or a combination thereof. The user device 205, therefore, grants a user access to data related to the power tool device(s) 100 (e.g., diagnostics information), and provides a user interface such that the user can interact with an electronic controller and/or diagnostic integrated circuit of the power tool device 100, as described in greater detail herein.

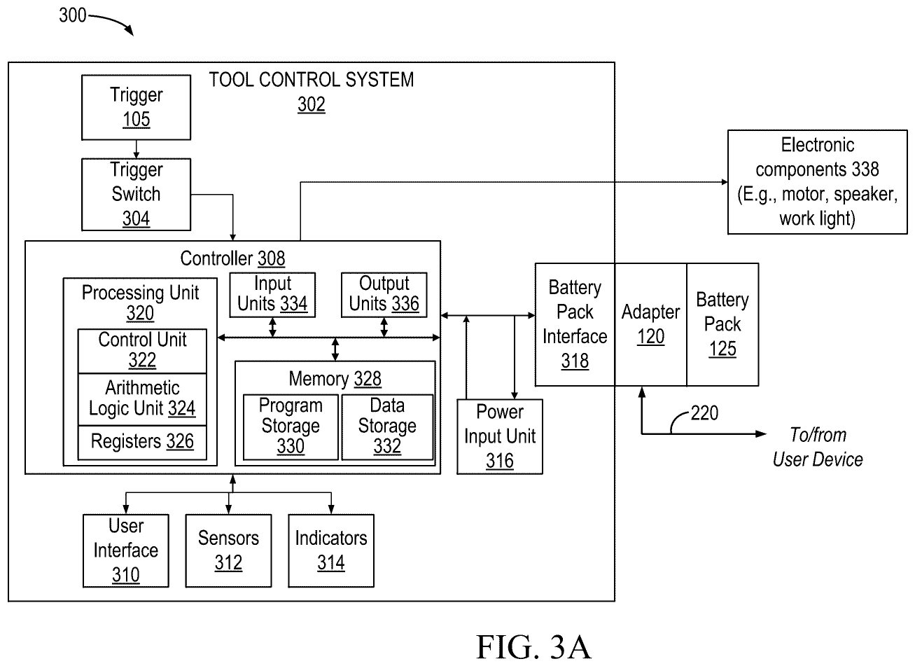

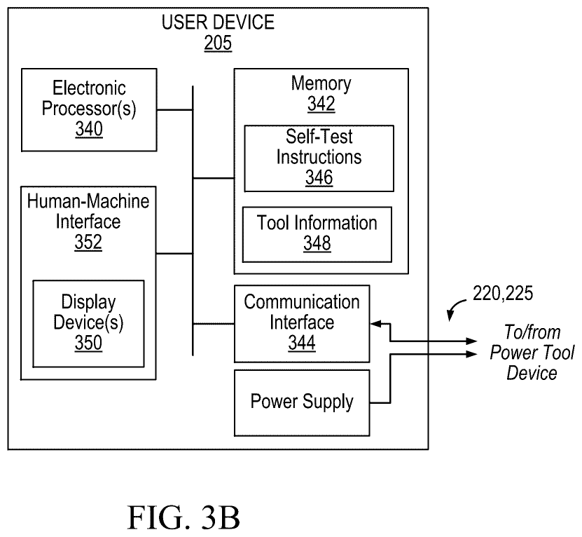

FIG. 3A illustrates a block diagram 300 of the power tool device 100, according to some examples. In these examples, the power tool device 100 includes a tool control system 302. The tool control system 302 may include the trigger 105 and a trigger switch 304 corresponding to trigger 105. The tool control system 302 may further include a controller 308, a user interface 310, one or more sensors 312, one or more indicators 314 (such as LED 110), a power input unit 316, and a battery pack interface 318. One or more of the components of the tool control system 302 may be mounted or otherwise coupled to and interconnected via one or more corresponding circuit boards (e.g., a printed circuit board (PCB).

The trigger switch 304 may provide a position of the trigger 105 to the controller 308. For example, the trigger switch 304 may be or include a potentiometer, a Hall effect sensor, an inductive sensor, or the like configured to indicate a position of the trigger 105. The one or more sensors 312 may include a power regulation sensor, a pressure sensor, an inductive sensor, and/or an inertial measurement unit sensor. The one or more sensors 312 may sense a tool characteristic and output a value indicative of the tool characteristic to the controller 308. In some examples, the trigger switch may also be considered a sensor of the one or more sensors 312.

The user interface 310 may include one or more mode buttons, dials, selectors, or the like that are operable to receive a user input and provide an indication of the user input to the controller 308. The indicators 314 may include one or more speakers, lights, or tactile feedback devices. The controller 308 may control the indicators 314 to provide information to a user. For example, the LED 110 illustrated in FIGS. 1-2 is an example of the indicator 314.

As shown in FIG. 3A, the controller 308 may include a processing unit 320 unit with a control unit 322, arithmetic logic unit 324, and registers 326. The controller 308 can also include input units 334 and output units 336 for communicating with other elements of the tool control system 302.

The memory 328 may include read-only memory (ROM), random access memory (RAM), other non-transitory computer-readable media, or a combination thereof. The memory 328 may include program storage 330 and data storage 332. For example, the memory 328 may store instructions (e.g., as part of the program storage 330) for the processing unit 320 to execute to implement functionality of the power tool device 100 described herein. In some examples, the instructions may include firmware that includes self-test firmware. The self-test firmware, when executed, may cause the controller 308 to perform one or more self-tests, as described further below. The memory 328 may also store tool information (e.g., as part of the data storage 332). As described herein, tool information may include diagnostic history, diagnostic test data, tool usage data, maintenance data, mode information, drive device information, and the like. The program storage 330 and data storage 332 may be specific to the power tool device 100.

The processing unit 320 may be configured to communicate with the memory 328 to store data and retrieve stored data. The processing unit 320 may be configured to receive instructions and data from the memory 328 and execute, among other things, the instructions. In some examples, through execution of the instructions by the processing unit 320, the controller 308 may perform one or more of the methods described herein and/or one or more self-tests described herein. The processing unit 320 may be, for example, a microprocessor, an application-specific integrated circuit (ASIC), or another suitable electronic device.

The battery pack interface 318 includes electrical terminals (e.g., of the battery pack interface 127) for interfacing with the adapter 120 and the battery pack 125, whichever may be coupled to the power tool device 100 at a particular moment. Power for the tool control system 302, and for the power tool device 100, may be received via the battery pack interface 318. The power received via the battery pack interface 318 may be received by and conditioned by the power input unit 316. The conditioned power may be provided to the controller 308 and other components of the tool control system 302.

The electronic components 338 may vary depending on a type of the power tool device 100. As one example, the electronic components 338 may include a switching circuit and a motor. The switching circuit may include a one or more power switching elements (e.g., field effect transistors (FETs), bipolar junction transistors (BJTs), or the like), which may be arranged as a switch bridge. The controller 308 may control the switching circuit to provide power from the power tool battery pack 125 to the motor to drive the motor. The motor may be a permanent magnet brushless motor, a brushed motor, or another type of motor. In other examples of the power tool device (e.g., a radio or work light), the electronic components may include a speaker or a light. The light may be a work light that illuminates when the trigger 105 of the power tool device 100 is engaged. The speaker may be a radio speaker that is controlled by the controller 308 to output audio (e.g., a radio broadcast, recorded audio or music stored on a computer readable medium, etc.). Additionally, the electronic components 338 may include a wireless communication module (e.g., a Bluetooth radio module, a Wi-Fi radio module, a Zigbee radio module, or the like). This wireless communication module enables the controller 308 to communicate with external devices wirelessly (e.g., with the user device 205).

As discussed with respect to FIGS. 1-2, the adapter 120 is configured to interface with the user device 205 via communication connection 220. In some examples, the communication connection 220 is configured to transfer both power and data between the user device 205 and the tool control system 302. In other examples, there may be separate cables and/or communication connections to separately transfer data and power between user device 205 and tool control system 302.

FIG. 3B illustrates a block diagram of an example of the user device 205 included in the communication system 200 of FIG. 2 according to some configurations. The user device 205 may be a computing device and may include a smart phone, a desktop computer, a terminal, a workstation, a laptop computer, a tablet computer, a smart watch or other wearable, a smart television or whiteboard, or the like. As illustrated in FIG. 3B, the user device 205 includes an electronic processor 340 (for example, a microprocessor, an application-specific integrated circuit (ASIC), or another suitable electronic device), a memory 342 (for example, a non-transitory, computer-readable medium), a communication interface 344, and a human-machine interface 352. The electronic processor 340, the memory 342, the communication interface 344, and the human-machine interface (HMI) 352 communicate wirelessly, over one or more communication lines or buses, or a combination thereof. It should be understood that the user device 205 may include additional components than those illustrated in FIG. 3B in various configurations and may perform additional functionality than the functionality described herein. For example, in some embodiments, the functionality described herein as being performed by the user device 205 may be distributed among servers or devices (including as part of services offered through a cloud service), may be performed by one or more tool control systems, or a combination thereof.

The communication interface 344 allows the user device 205 to communicate with devices external to the user device 205. For example, as illustrated in FIGS. 2, 3A, and 3B, the user device 205 may communicate with the tool control system 302, the power tool adapter 120, the power tool device 100, the server 210, or a combination thereof through the communication interface 344. The communication interface 344 may include a port for receiving a wired connection (e.g., the wired communication connection 225 via data port 115, communication connection 220 of FIGS. 1 and 2, and or a wired connection to the network 215 or server 210), a transceiver for establishing a wireless connection (e.g., over one or more communication networks, such as the Internet, local area network, a wide area network, and the like), or a combination thereof.

The electronic processor 340 is configured to access and execute computer-readable instructions (“software”) stored in the memory 342. The software may include firmware, one or more applications, program data, filters, rules, one or more program modules, and other executable instructions. For example, the software may include instructions and associated data for performing a self-test, including the methods described herein.

As illustrated in FIG. 3B, the memory 342 may store a self-test instructions 346 (also referred to herein as “instructions 346”), executable by the electronic processor 340. As described in more detail below, the electronic processor 340 may execute the self-test instructions 346 to communicate with the power tool device 100, to instruct or command that the power tool device 100 execute one or more self-tests, and/or to retrieve tool diagnostics information. As also illustrated in FIG. 3B, the memory 342 may also store tool information 348. The tool information 348 stored in the memory 342 may include tool information received (or otherwise retrieved from) one or more of the power tool devices 100, such as, e.g., via the power tool adapter 120 or the data port 115, as described in greater detail herein. In some configurations, the electronic processor 340 may execute the instructions 346 in order to generate and provide a graphical user interface (“GUI”) including the tool information 348, as described in greater detail herein.

As illustrated in FIG. 3B, in some configurations, the user device 205 may include the HMI 352 for interacting with a user. The HMI 352 may include one or more input devices, one or more output devices, or a combination thereof. Accordingly, in some configurations, the HMI 352 allows a user to interact with (e.g., provide input to and receive output from) the user device 205. For example, the HMI 352 may include a keyboard, a cursor-control device (e.g., a mouse), a touch screen, a scroll ball, a mechanical button, a display device (e.g., a liquid crystal display (LCD)), a printer, a speaker, a microphone, another type of input device, another type of output device, or a combination thereof. As illustrated in FIG. 3B, in some configurations, the HMI 352 includes a display device 350. The display device 450 may be included in the same housing as the user device 205 or may communicate with the user device 205 over one or more wired or wireless connections. For example, in some configurations, the display device 350 is a touchscreen included in a laptop computer or a tablet computer. In other configurations, the display device 350 is a monitor, a television, or a projector coupled to a terminal, desktop computer, or the like via one or more cables.

A user may use the user device 205 to interact with the power tool device 100 via a connection provided by the power tool adapter 120 or data port 115. As one example, a user may use the user device 205 to diagnose or identify failed tool electronics based on execution of the self-test instructions 346.

Although the user device 205 is primarily described with respect one power tool device 100, in some examples, the user device 205 may interact with a plurality of power tool devices that are similar to the power tool device 100 in a similar manner as described with respect to the power tool device 100 herein, although each of the plurality of power tool devices may be a different type of power tool device (e.g., power tool, power tool battery pack, battery charger, etc.).

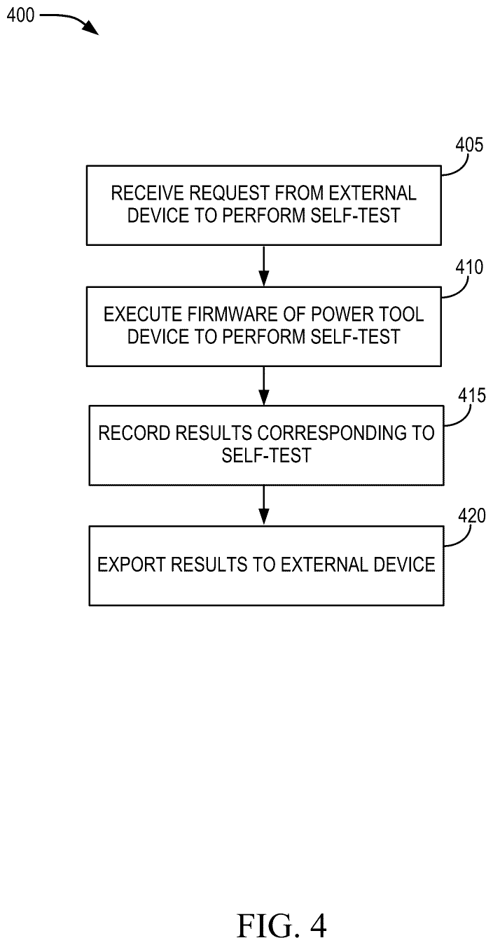

Over time, while power tool devices are in use in the field by users, power tool devices may experience errors, faults, or malfunctions. In part because of the complexity of modern power tool devices, determining causes of errors, faults, or malfunctions of a power tool device may be challenging. Features of the systems, power tool devices, and processes described herein, including a process 400 of FIG. 4 described below, enable a device and an individual (e.g., a service technician) to more quickly and accurately diagnosis an error, fault, or malfunction of the power tool device 100 in the field. For example, rather than simply identifying that a control system or corresponding circuit board is malfunctioning, using the systems devices, and processes described herein, a service technician can identify particular electronics or features of the power tool device 100, control system 302, or corresponding circuit board that may be experiencing an issue. This more granular information may be used, for example, for improving future designs, fixing a currently malfunctioning power tool device, and/or evaluating warranty claims.

FIG. 4 illustrates a flowchart of a process 400 for performing tool diagnostics on one or more of the power tool devices 100, which can be implemented using any of the systems described herein. However, in some embodiments, the process 400 is implemented by another system having additional components, fewer components, alternative components, etc. In some specific cases, the process 400 can be implemented using a power tool device 100. Additionally, although the blocks of the process 400 are illustrated in a particular order, in some embodiments, one or more of the blocks can be executed partially or entirely in parallel, can be executed in a different order than illustrated in FIG. 4, or can be bypassed. For illustration purposes, the process 400 is generally described as being implemented by the power tool device 100 in the context of the communication system 200 in FIG. 2. However, in other embodiments, other devices or components of the communication system 200, or other components or devices of other systems, can implement or be used in the process 400.

In block 405, a power tool device can receive a request from an external device to perform a self-test. For example, the power tool device 100 can receive a request from the user device 205 to perform the self-test. More particularly, an electronic controller (e.g., the controller 308) of the power tool device 100 may receive the request. In some examples, the request may be received via a power tool battery pack interface (e.g., battery pack interface 318 of tool control system 302). For example, battery pack interface 318 may include one or more terminals, which receive the request from the user device 205 via the adapter 120 coupled to the battery pack interface 318. In another example, the controller 308 may receive the request from the user device 205 via the data port 115 (e.g., via one or more terminals of the data port 115). The self-test may include one or more diagnostics tests of one or more components of the power tool device. The request may specify (e.g., via test identifiers) which of the one or more diagnostics tests to perform for example.

In block 410, the process 400 may include executing firmware of the power tool device to perform the self-test. In particular, the electronic controller (e.g., the controller 308) may execute firmware of the power tool device 100 in response to receiving the request at block 405. The firmware may activate any one or more functions of the power tool in order to perform a single or a plurality of tasks associated with the requested self-test. For example, controller 308, as illustrated in FIG. 3A, may execute firmware stored in the memory 328 as part of the program storage 330 to perform the self-test, which, as noted, may include one or more diagnostics tests. Executing the firmware may include causing one or more of the electronic components 338, the controller 308, the user interface 310, the sensors 312, the trigger switch 304, and/or the indicators 314 to perform one or more tasks to implement the self-test.

For example, as described above, the electronic components 338 of the power tool device 100 can include one or more of a Bluetooth radio module, a switching network, a motor, a speaker, a light, and/or other components. The controller 308 executing the firmware may perform diagnostics testing on one or more of these components, and/or of other components of the power tool device 100. To execute the self-test, the controller 308 may, for example: communicate with the Bluetooth radio module (e.g., send a message and await or receive a response) to determine whether that the Bluetooth radio module is operating appropriately (e.g., without malfunction); wirelessly communicate with a wireless device connected via the Bluetooth radio module (e.g., send a message to the wireless device and await or receive a response) to determine whether that the Bluetooth radio module is operating appropriately; store and retrieve sample or test data to/from the memory 328 to determine whether the memory 328 is operating appropriately; store and retrieve sample or test data to/from a removable memory drive (e.g., a USB or flash drive) coupled to the tool control system 302 to determine whether the removable memory drive is operating appropriately; receive and analyze sensor data from one or more of the sensors 312 (e.g., a current sensor, temperature sensor, inductance sensor, inertial measurement unit (IMU), voltage sensor, pressure sensors, etc.) to confirm that the sensors 312 are outputting data within an expected range and, from that, infer that the sensors are operating appropriately; control one or more of the electronic components 338 and monitor (e.g., with the sensors 312) a change in current or other electric characteristic to determine whether the change is within an expected range and, from that, infer that the one or more electronic components 338 are operating appropriately; receive and analyze sensor data from a current sensor of the sensors 312 to determine whether current to the controller 308 while the power tool device 100 is idle is within an expected range and, from that, infer that the sensors are operating appropriately; and/or receive sensor data from a pressure sensor of the sensors 312 that monitors pressure in a hydraulic system (e.g., in a line or tank) and determine whether the pressure sensor is outputting data within an expected range and, from that, infer that the pressure sensor and/or hydraulic system is operating appropriately. In some examples, the self-test includes a diagnostics test of power switching elements (e.g., field effect transistors (FETs) of a switching network of the electronic components 338 that drives a motor of the electronic components 338. For example, the controller 308 executes the firmware to control one or more of the power switching elements and monitors (e.g., via a current sensor of the sensors 312) whether the resulting current draw indicates a malfunction or an error (e.g., a short) in the power switching elements. In some examples, the self-test includes one or more other or additional diagnostics tests for the control system 302 and/or the power tool device 100.

In some examples, the external device (e.g., the user device 205) that sent the request for the self-test at block 405 may output an additional request during the execution of the firmware. This additional request may be a request for an action to be performed by a user while the self-test is being executed. For example, the request may be for the user to pull a trigger of the power tool and/or to actuate another actuator (e.g., button, lever, switch, dial, etc.) of the power tool. In another example, the request may be for the user to confirm or describe an illumination of one or more light emitting diodes (LEDs) on the power tool, an audible beep or sound of an indicator 314, or other human perceptible tool action. The request may be output on the display device(s) 350 (e.g., as text and/or graphics) and/or may be output via a speaker of the HMI 352 (e.g., as spoken instructions).

In block 415, the process 400 may include recording the results corresponding to the self-test. In particular, the electronic controller executing the firmware may record the results. For example, the controller 308 may store the results (also referred to as results data) of the self-test in the memory 328 as part of the data storage 332. The results may vary depending on the particular self-test. For example, the results data may include sensors data recorded from the sensors 312 such as, for example, sensor data from a power regulation sensor, a current sensor, a voltage sensor, a temperature sensor, a pressure sensor, an inductive sensor, and/or an inertial measurement unit sensor of the sensors 312. Additionally or alternatively, the controller 308 may analyze the sensor data (or a portion thereof) obtained during the self-test, and store the analysis results as the test result. For example, the diagnostic controller 508 may compare the sensor data to one or more thresholds to determine whether the sensor data indicates an issue or is within an acceptable range, and may store the results of the comparison as the test result, alone or along with the underlying sensor data. Thus, the results data include the underlying (raw) sensor data obtained during the self-test, and/or may include whether the recorded data met, exceeded, and/or failed to meet a specified range or threshold. Accordingly, for example, the results data may include a binary indication (e.g., pass or fail) for each sub-system or component tested during the self-test, or may include an indication of each sub-system or component that failed (or passed). For example, the results data may specify that one or more power switching elements of a switching network of the electronic components 338 included a short, that a flash drive is not operating properly, that current to the controller 308 is low (e.g., when the power tool device 100 is idle), that an LED of indicators 314 is not illuminating, that a wireless radio of the electronic components 338 is not operating properly (e.g., responses to messages from the controller 308 to or via the wireless radio were not received within a certain time window), etc.

In block 420, the process 400 can export the results to an external device. In particular, the electronic controller may export the results to the external device that requested the self-test. For example, the controller 308 may export the results (e.g., the results data) to the user device 205 via the adapter 120 and the communication connection 220, or via the data port 115 and communication connection 225, to the communication interface 344 of user device 205.

In some examples, the user device 205 may store the results, display the results on the display device(s) 350, and/or export the results to a further device (e.g., the server 210 via the network 215). In some examples, the user device 205 adds additional information to the results to provide modified results. For example, when the user device 205 outputs an additional request to the user and involves requesting a user response from the user via the HMI 352, the user device 205 may record that user response. The user device 205 may then add that user response as additional information to the results. Thus, for example, when the user device 205 outputs an additional request to the user to confirm that a light was illuminated or other tool action occurred as part of a diagnostic test, the user response may be included as part of the results of the diagnostic test. The user device 205 may store these modified results, display the modified results on the display device(s) 350, and/or export the modified results to a further device (e.g., the server 210 via the network 215).

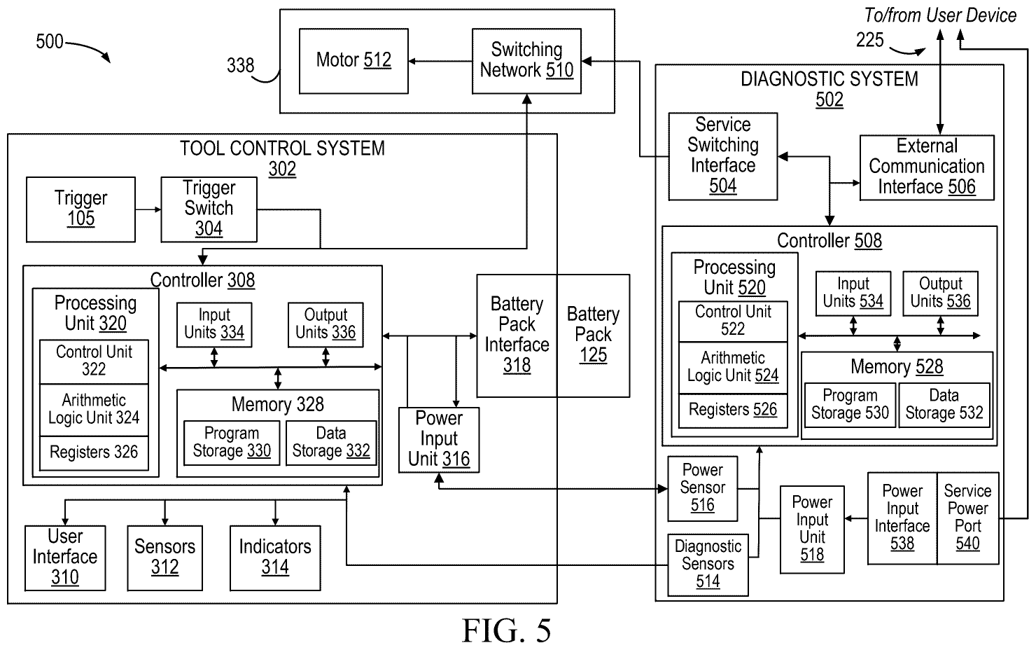

FIG. 5 illustrates a block diagram 500 of the power tool device 100, according to some examples. In these examples, the power tool device 100 includes a tool control system 302 and a diagnostic system 502. The tool control system 302 and its associated components in FIG. 5 are similar to the tool control system 302 shown and described above with respect to FIG. 3A. Although it is not illustrated in FIG. 5, an adapter (e.g., adapter 120) may be connected between battery pack 125 and battery pack interface 318 to enable a user device to communication with an external device (such as user device 205, described above with respect to FIGS. 2, 3A-3B, and 4). Thus, the power tool device 100 as implemented in FIG. 5 may also execute the process 400 of FIG. 4.

In the example of FIG. 5, the power tool device 100 further includes the diagnostic system 502 connected to the tool control system 302, and includes a switching network 510 and a motor 512 as the electronic components 338. In some examples of the power tool device 100, other electronic components (e.g., for non-motorized power tools) are provided, for example, one or more of lights, displays, speakers, and the like. In some examples, the diagnostic system 502 may be implemented as a diagnostics integrated circuit within a power tool device (e.g., power tool device 100). For example, the diagnostic system 502 may be provided on a circuit board (e.g., a printed circuit board) that is supported by and housed within a tool housing of the power tool device 100 (e.g., within the main body 102 in the example of FIG. 1). Both the tool control system 302 and the diagnostic system 502 may be supported by and housed within a tool housing of the power tool device 100. In some examples, the tool control system 302 and the diagnostic system 502 may be provided on separate circuit boards within the tool housing.

The diagnostic system 502 includes a service switching interface 504, an external communications interface 506, a diagnostic controller 508, one or more diagnostic sensors 514, a power sensor 516, a power input unit 518, a power input interface 538, and a service power port 540.

The diagnostic system 502 may be independently powered relative to the tool control system 302. That is, the diagnostic system 502 may not receive power from the battery pack interface 318 or the battery pack 125; rather, the diagnostic system 502 may receive power to power the diagnostic controller 508 and other components of the diagnostic system 502 via the service power port 540. Thus, the diagnostic system 502 may remain isolated, offline, and/or unpowered during normal tool operation (e.g., when the switching network 510 is being controlled by the tool control system 302 to drive the motor 512 by applying power from the battery pack 125). Further, the diagnostic system 502 may be powered, selectively, for performance of diagnostic testing, as explained further below.

The power received via the service power port 540 may be received by the power input interface 538 (e.g., terminals) and conditioned by the power input unit 518. The conditioned power may be provided to the diagnostic controller 508 and other components of the diagnostic system 502.

The diagnostic sensors 514 may include one or more temperature, one or more current, one or more voltage sensors, one or more pressure sensors, one or more inertial measure measurement unit (IMU) sensors, one or more vibration sensors, one or more magnetic field sensors, one or more inductance sensors, and/or one or more additional sensors for monitoring features and components of the power tool device 100 including features and components of the tool control system 302, the switching network 510, and the motor 512. The power sensor 516 may further include one or more current sensors and/or one or more voltage sensors for monitoring power at the power input unit 316 received via the battery pack interface 318. Although illustrated separately, the power sensor 516 may also be referred to and considered as a diagnostic sensor (e.g., similar to the diagnostic sensors 514). The sensors 514 and 516 may output sensor data indicative of the characteristics sensed by these respective sensors to the diagnostic controller 508.

As illustrated in FIG. 5, the service switching interface 504 provides a connection or interface to the switching network 510 that is separate from the connection between the tool control system 302 and the switching network 510. This service switching interface 504 can provide the diagnostic system 502 isolation from the switching network 510 when the diagnostic system is unpowered or offline. The service switching interface 504 may include a switch, for example, a field effect transistor (FET) or other power switching element, to selectively connect and disconnect the diagnostic system 502 from the switching network 510. Additionally, the switch may selectively connect and disconnect the tool control system 302 from the switching network 510. For example, the switch may include a first state in which the switch connects the tool control system 302 to the switching network 510, and a second state in which the switch connects the diagnostic system 502 to the switching network 510. The first state may be when the diagnostic system 502 is offline, and the second state may be when the diagnostic system 502 is online. Additionally, the service switching interface 504 may include one or more current sensors to sense current through the switching network 510. Although the service switching interface 504 is illustrated separate from the diagnostic sensors 514, the one or more current sensors of the service switching interface 504 may also be referred to and considered as a diagnostic sensor (e.g., similar to the diagnostic sensors 514) and may output sensor data indicative of the current sensed by the one or more current sensors to the diagnostic controller 508.

The diagnostic controller 508 of the diagnostic system 502 may be generally similar to the controller 308, and like numbers plus 200 are used for like parts. Thus, as illustrated, the diagnostic controller 508 may include a processing unit 520 with a control unit 522, arithmetic logic unit 524, and registers 526. Moreover, a memory 528 may have program storage 530 and data storage 532. The controller can also include input units 534 and output units 536. The processing unit 520 may be, for example, a microprocessor, an application-specific integrated circuit (ASIC), or another suitable electronic device. In some examples, the diagnostic controller 508 and/or the processing unit 520 may be implemented as a field programmable gate array (FPGA) with an advanced RISC machine (ARM) core.

An external device (e.g., the user device 205) may connect to the diagnostic system 502 via the external communication interface 506 and/or the service power port 540, as illustrated in FIG. 5. In some examples, the external communication interface 506 and the service power port 540 may be a combined port that can allow for communication, as well as power transfer between the external device and the diagnostic system 502. For example, as described above with respect to FIGS. 1 and 2, the external communication interface 506 and/or the service power port 540 may correspond to the data port 115 connected to the communication connection 225.

When power is received via the service switching interface 504, the diagnostic controller 508 may be powered and brought online, and may communicate with an external device (e.g., the user device 205) via the external communication interface 506). For example, as described further below, when the diagnostic system 502 online and controlling the operation of a power tool device 100 to perform diagnostic testing, any results and/or operational data collected via one or more of the diagnostic sensors 514 or the power sensor 516 may be exported via the external communication interface 506 to the user device 205.

As described above, the diagnostic system 502 can receive power from an external device via the service power port 540. Therefore, the power used to run the diagnostic system 502 can be separate from the power from the battery pack 125 supplied to the tool control system 302 and other components of the power tool device 100. As also described above, the service switching interface 504 can isolate the diagnostic system 502 from damage caused by failure of the tool control system 302 and/or the switching network 510. The separate power supply and isolation from the switching network 510 may allow the diagnostic system 502 to be partly or completely isolated from the tool control system 302 and other components of the power tool device 100. Therefore, if a failure occurs to the tool control system 302 (e.g., a power failure), the switching network 510, or other component of the power tool device 100, the diagnostic system 502 can remain unaffected by the failure. Moreover, the power separately supplied via the service power port 540 allows the diagnostic system 502 to remain offline or powered-off while not in use, rather than being powered by the battery pack 125. Thus, adding the diagnostic system 502 to the power tool device 100 does not impact battery life of the battery pack 125. Further, including the diagnostic system 502 as a separate component in the power tool device 100, rather than solely relying on the controller 308 to perform self-tests, provides more robust diagnostic testing of the power tool device 100. For example, the diagnostic system 502 may test aspects of the power tool device 100 and the tool control system 302, including the controller 308, to provide test results independent of the controller 308. Thus, if the controller 308 is experiencing a malfunction that renders the controller 308 unable to execute a self-test or to generate inaccurate test results, the diagnostic system 502 may be able to detect such malfunctions and provide valuable insight to a technician that would otherwise be unavailable or difficult to obtain.

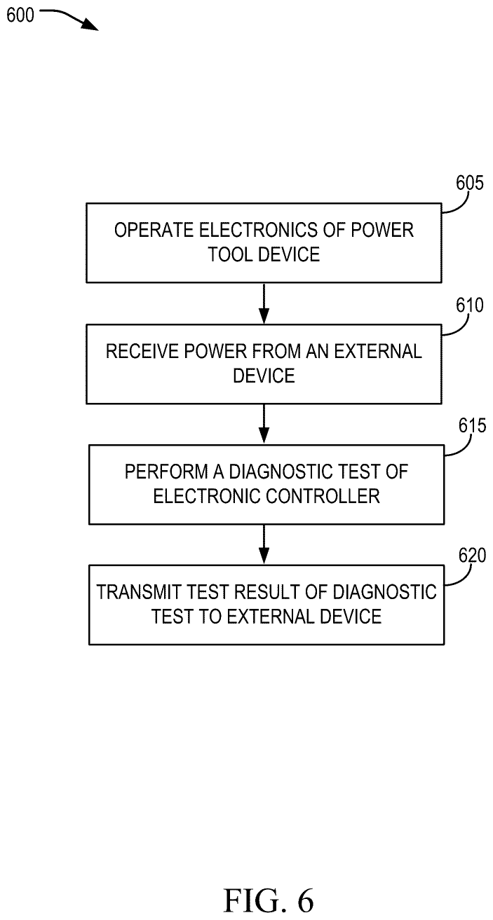

FIG. 6 illustrates a flowchart of a process 600 for performing tool diagnostics on one or more of the power tool devices 100, which can be implemented using any of the systems described herein. However, in some embodiments, the process 600 is implemented by another system having additional components, fewer components, alternative components, etc. In some specific cases, the process 600 can be implemented using a power tool device 100. Additionally, although the blocks of the process 600 are illustrated in a particular order, in some embodiments, one or more of the blocks can be executed partially or entirely in parallel, can be executed in a different order than illustrated in FIG. 6, or can be bypassed. For illustration purposes, the process 600 is generally described as being implemented by the power tool device 100 in the context of the communication system 200 in FIG. 2. However, in other embodiments, other devices or components of the communication system 200, or other components or devices of other systems, can implement the process 600.

In block 605, the process 600 includes operating electronics of a power tool device. For example, an electronic controller, such as the controller 308 of tool control system 302, as described above with respect to FIGS. 3A, 3B, and 5 may control the electronic components 338 to operate. As discussed above, the electronic components 338 may vary by power tool device type. In some examples, the electronic components 338 may include a motor, a speaker, a work light, or any other electronic components of the power tool device 100. In some examples, with reference to FIG. 5, the operation of the electronics may include the controller 308 controlling the switching network 510 to apply power from the power tool battery pack 125 to the motor 512 of the power tool device 100 to drive the motor 512.

In block 610, the process 600 includes a diagnostic integrated circuit of the power tool device receiving power from an external device. For example, with reference to FIG. 5, the diagnostic system 502 (a diagnostic integrated circuit) of the power tool device 100 may receive power from the user device 205 (an external device). The diagnostic integrated circuit may include a processing circuit (e.g., processing unit 520) that is separate from processor of the electronic controller (e.g., processing unit 320), as well as a diagnostic sensor (e.g., diagnostic sensors 514), and an external communication interface (e.g., external communication interface 506). In some examples, the sensor can be a power regulation sensor, a pressure sensor, an inductive position sensor (also referred to as a ZMID sensor), an inertial measurement unit sensor, or the like. The user device 205 may supply the power to the diagnostic system 502 via communication connection 225 (FIG. 2), and the diagnostic system 502 may receive the power at the service power port 540 (FIG. 5). As described above, the power received at the service power port 540 may be provided to the diagnostic controller 508 and other components of the diagnostic system 502 via the power input interface 538 and the power input unit 518. Thus, the diagnostic controller 508 and the electronic controller 308 may receive power from two different, isolated power sources. That is, the electronic controller 308 may receive power from the battery pack 125 via the battery pack interface 318, while the diagnostic controller 508 may receive power from the user device 205 via the service power port 540.

When the controller 508 receives the power, the diagnostic controller 508 may come online (e.g., may be powered on, enabled, started up, etc.). For example, the diagnostic controller 508 (e.g., the processing unit 520) may execute instructions from the memory 528 (e.g., boot loader instructions followed by diagnostic firmware instructions) to begin operation.

In block 615, the process 600 includes performing a diagnostic test of the electronic controller using the processing circuit. For example, with reference to FIG. 5, the processing unit 520 of the diagnostic controller 508 may execute firmware instructions that cause the diagnostic controller 508 to implement a diagnostic test of the electronic controller 308. In some examples, the diagnostic test may include one or more diagnostic checks of one or more functionalities of one or more subsystems of the power tool device 100. For example, the diagnostic test may test the functionalities of a Bluetooth radio module of the electronic components 338, a flash integrated circuit of the electronic components 338 used for external data storage, a transistor (e.g., a FET of the switching network 510), a pressure sensor of the sensors 312, the trigger switch 304, a microcontroller unit (e.g., the controller 308), and/or other components of the power tool device 100.

In some examples, the diagnostic test of the electronic controller 308 includes a test of a power supply of the electronic controller 308. For example, the diagnostic controller 508 may receive sensor data output by the power sensor 516 indicative of power characteristics at the power input unit 316 (and, thus, of power being received by the controller 308). In some examples, the diagnostic test is performed while the controller 308 is in a standby or sleep state (e.g., a certain amount of time after a most recent trigger pull after which the controller 308 enters such a state). The controller 308 is unable to perform such a test as a self-test when the controller 308 is in a standby or sleep state, as performing this test would cause the controller 308 to be brought out of the sleep state and back online. However, the diagnostic controller 508, being an independent component with separate power supply, may perform this diagnostic test while the controller 308 is in a standby or sleep state.

The diagnostic controller 508 may store the sensor data received from the power sensor 516 (e.g., for later output and analysis) and/or may determine whether the sensor data indicates that power being received by the controller 308 is within an acceptable range (e.g., within a voltage range, a current range, and/or a power range) by comparing the power characteristics to one or more thresholds defining the range(s). In some examples, the diagnostic controller 508 may receive sensor data output by one or more of the diagnostic sensors 514 as part of the diagnostic test. For example, the one or more diagnostic sensors 514 may monitor (and output sensor data indicative of) current and/or voltage at one or more pins or terminals of an integrated circuit of the controller 308 or other components of the tool control system 302. This sensor data may indicate, for example, characteristics of control signals that the controller 308 outputs to the electronic components 338 (e.g., to the switching network 510), the indicators 314, or other components of the power tool device 100. This sensor data may also indicate, for example, characteristics of signals being received by the controller 308 (e.g., from the user interface 310, the sensors 312, or other components of the power tool device 100). As another example, the sensor data may indicate temperature of a component or area of the power tool device 100, pressure of a component or area of the power tool device 100, vibration of a component or area of the power tool device 100, or another characteristic of the power tool device 100.

In some examples, the diagnostic controller 508 performs the diagnostic test, or a portion thereof, while the controller 308 is controlling the electronic components 338 using power from the battery pack 125 (e.g., in response to a trigger pull of the trigger 105). In some examples, the diagnostic controller 508 performs the diagnostic test, or a portion thereof, while the controller 308 is idle and not actively controlling the electronic components 338 using power from the battery pack 125 (e.g., while the trigger 105 is released).

In some examples, the diagnostic controller 508 performs the diagnostic test in response to receiving a request from an external device (e.g., the user device 205). For example, the diagnostic controller 508 may receive the request via the external communications interface 506 (e.g., from the user device 205 via the data port 115). In some examples, the external device (e.g., the user device 205) that sent the request for the self-test at block 405 may output an additional request during the execution of the diagnostic test. This additional request may be a request for an action to be performed by a user while the diagnostic test is being executed. For example, the request may be for the user to pull a trigger of the power tool and/or to actuate another actuator (e.g., button, lever, switch, dial, etc.) of the power tool. In another example, the request may be for the user to confirm or describe an illumination of one or more light emitting diodes (LEDs) on the power tool, an audible beep or sound of an indicator 314, or other human perceptible tool action. The request may be output on the display device(s) 350 (e.g., as text and/or graphics) and/or may be output via a speaker of the HMI 352 (e.g., as spoken instructions).

In some examples, the diagnostic controller 508 may store the sensor data (or a portion thereof) obtained during the diagnostic test, whether from the power sensor 516 and/or the diagnostic sensor(s) 514, as a test result. In some examples, the diagnostic controller 508 may analyze the sensor data (or a portion thereof) obtained during the diagnostic test, whether from the power sensor 516 and/or the diagnostic sensor(s) 514, and store the analysis results as the test result. For example, the diagnostic controller 508 may compare the sensor data to one or more thresholds to determine whether the sensor data indicates an issue or is within an acceptable range, and may store the results of the comparison as the test result, alone or along with the underlying sensor data. The test results that are stored may also be referred to as test result data.

In block 620, the process 600 includes transmitting, by the processing circuit, a test result of the diagnostic test to an external device via an external communication interface. For example, with reference to FIG. 5, the diagnostic controller 508, or the processing unit 520 thereof, may transmit the test result(s) generated in block 615 to the user device 205 via the external communication interface 506.

In some examples, the user device 205 may store the test result(s), display the test result(s) on the display device(s) 350, and/or export the test result(s) to a further device (e.g., the server 210 via the network 215). In some examples, the test result(s) may be used by a service technician to identify when components of a power tool are not functioning as expected, and classify the results into specific tool failures.

In some examples, the user device 205 adds additional information to the results to provide modified results. For example, when the user device 205 outputs an additional request to the user and involves requesting a user response from the user via the HMI 352, the user device 205 may record that user response. The user device 205 may then add that user response as additional information to the results. Thus, for example, when the user device 205 outputs an additional request to the user to confirm that a light was illuminated or other tool action occurred as part of a diagnostic test, the user response may be included as part of the results of the diagnostic test. The user device 205 may store these modified results, display the modified results on the display device(s) 350, and/or export the modified results to a further device (e.g., the server 210 via the network 215).

Accordingly, the various systems and methods described herein, among other things, may perform diagnostic testing to, for example, test each FET of a switching network that drives a motor, to test each LED of a power tool device, to test a trigger (e.g., test detection of a trigger pull by trigger switch and/or controller), to test a motor (e.g., test that the motor operates in response to a trigger pull using current sensors and/or Hall sensors that are positioned to detect motor rotation or position), to test power draw of various components of the power tool device, and/or to test that one or more sensors (e.g., an IMU) is generating sensor data that is within an expected range, and to provide results of the diagnostic testing to a user device.

It is to be understood that the disclosure is not limited in its application to the details of construction and the arrangement of components set forth in the following description or illustrated in the following drawings. The disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

As used herein, unless otherwise limited or defined, discussion of particular directions is provided by example only, with regard to particular embodiments or relevant illustrations. For example, discussion of “top,” “front,” or “back” features is generally intended as a description only of the orientation of such features relative to a reference frame of a particular example or illustration. Correspondingly, for example, a “top” feature can sometimes be disposed below a “bottom” feature (and so on), in some arrangements or embodiments. Further, references to particular rotational or other movements (e.g., counterclockwise rotation) is generally intended as a description only of movement relative to a reference frame of a particular example of illustration.

In some embodiments, including computerized implementations of methods according to the disclosure, can be implemented as a system, method, apparatus, or article of manufacture using standard programming or engineering techniques to produce software, firmware, hardware, or any combination thereof to control a processor device (e.g., a serial or parallel processor chip, a single- or multi-core chip, a microprocessor, a field programmable gate array, any variety of combinations of a control unit, arithmetic logic unit, and processor register, and so on), a computer (e.g., a processor device operatively coupled to a memory), or another electronically operated controller to implement aspects detailed herein. Accordingly, for example, embodiments of the disclosure can be implemented as a set of instructions, tangibly embodied on a non-transitory computer-readable media, such that a processor device can implement the instructions based upon reading the instructions from the computer-readable media. Some embodiments of the disclosure can include (or utilize) a control device such as an automation device, a computer including various computer hardware, software, firmware, and so on, consistent with the discussion below. As specific examples, a control device can include a processor, a microcontroller, a field-programmable gate array, a programmable logic controller, logic gates etc., and other typical components that are known in the art for implementation of appropriate functionality (e.g., memory, communication systems, power sources, user interfaces and other inputs, etc.). Also, functions performed by multiple components can be consolidated and performed by a single component. Similarly, the functions described herein as being performed by one component can be performed by multiple components in a distributed manner. Additionally, a component described as performing particular functionality can also perform additional functionality not described herein. For example, a device or structure that is “configured” in a certain way is configured in at least that way, but can also be configured in ways that are not listed.

The term “article of manufacture” as used herein is intended to encompass a computer program accessible from any computer-readable device, carrier (e.g., non-transitory signals), or media (e.g., non-transitory media). For example, computer-readable media can include but are not limited to magnetic storage devices (e.g., hard disk, floppy disk, magnetic strips, and so on), optical disks (e.g., compact disk (CD), digital versatile disk (DVD), and so on), smart cards, and flash memory devices (e.g., card, stick, and so on). Additionally, it should be appreciated that a carrier wave can be employed to carry computer-readable electronic data such as those used in transmitting and receiving electronic mail or in accessing a network such as the Internet or a local area network (LAN). Those skilled in the art will recognize that many modifications can be made to these configurations without departing from the scope or spirit of the claimed subject matter.

Certain operations of methods according to the disclosure, or of systems executing those methods, can be represented schematically in the figures or otherwise discussed herein. Unless otherwise specified or limited, representation in the figures of particular operations in particular spatial order may not necessarily require those operations to be executed in a particular sequence corresponding to the particular spatial order. Correspondingly, certain operations represented in the figures, or otherwise disclosed herein, can be executed in different orders than are expressly illustrated or described, as appropriate for particular embodiments of the disclosure. Further, in some embodiments, certain operations can be executed in parallel, including by dedicated parallel processing devices, or separate computing devices configured to interoperate as part of a large system.

As used herein in the context of computer implementation, unless otherwise specified or limited, the terms “component,” “system,” “module,” etc. are intended to encompass part or all of computer-related systems that include hardware, software, a combination of hardware and software, or software in execution. For example, a component can be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) can reside within a process or thread of execution, can be localized on one computer, can be distributed between two or more computers or other processor devices, or can be included within another component (or system, module, and so on).

In some implementations, devices or systems disclosed herein can be utilized or installed using methods embodying aspects of the disclosure. Correspondingly, description herein of particular features, capabilities, or intended purposes of a device or system is generally intended to inherently include disclosure of a method of using such features for the intended purposes, a method of implementing such capabilities, and a method of installing disclosed (or otherwise known) components to support these purposes or capabilities. Similarly, unless otherwise indicated or limited, discussion herein of any method of manufacturing or using a particular device or system, including installing the device or system, is intended to inherently include disclosure, as embodiments of the disclosure, of the utilized features and implemented capabilities of such device or system.

As used herein, unless otherwise defined or limited, ordinal numbers are used herein for convenience of reference based generally on the order in which particular components are presented for the relevant part of the disclosure. In this regard, for example, designations such as “first,” “second,” etc., generally indicate only the order in which the relevant component is introduced for discussion and generally do not indicate or require a particular spatial arrangement, functional or structural primacy or order.

As used herein, unless otherwise defined or limited, directional terms are used for convenience of reference for discussion of particular figures or examples. For example, references to downward (or other) directions or top (or other) positions can be used to discuss aspects of a particular example or figure, but do not necessarily require similar orientation or geometry in all installations or configurations.

As used herein, unless otherwise defined or limited, the phase “and/or” used with two or more items is intended to cover the items individually and the items together. For example, a device having “a and/or b” is intended to cover: a device having a (but not b); a device having b (but not a); and a device having both a and b.

This discussion is presented to enable a person skilled in the art to make and use embodiments of the disclosure. Various modifications to the illustrated examples will be readily apparent to those skilled in the art, and the generic principles herein can be applied to other examples and applications without departing from the principles disclosed herein. Thus, embodiments of the disclosure are not intended to be limited to embodiments shown, but are to be accorded the widest scope consistent with the principles and features disclosed herein and the claims below. The following detailed description is to be read with reference to the figures, in which like elements in different figures have like reference numerals. The figures, which are not necessarily to scale, depict selected examples and are not intended to limit the scope of the disclosure. Skilled artisans will recognize the examples provided herein have many useful alternatives and fall within the scope of the disclosure.

Various features and advantages of the disclosure are set forth in the following claims.

1. A method of performing tool diagnostics, the method comprising:
receiving, by an electronic controller of a power tool device, a request from an external device to perform a self-test;
in response to the request, executing, by the electronic controller, firmware of the power tool device to perform the self-test;
recording, by the electronic controller executing the firmware, results corresponding to the self-test; and
exporting, by the electronic controller, the results to the external device.

2. The method of claim 1, wherein the request from the external device is received by the electronic controller via terminals of a power tool battery pack interface of the power tool device.

3. The method of claim 1, further comprising requesting, via the external device, an action be performed by a user while the self-test is performed.

4. The method of claim 3, wherein the action comprises the user pulling a trigger of the power tool device.

5. The method of claim 3, wherein the action comprises the user confirming an illumination of a light emitting diode (LED), and wherein performing the self-test comprises illuminating the LED.

6. The method of claim 1, wherein the self-test comprises a plurality of diagnostic tests of one or more components of the power tool device, the plurality of diagnostic tests including a diagnostic test of at least one selected from a group of: a radio module, a transistor, a sensor, or a storage module.

7. The method of claim 1, further comprising:
receiving, by a diagnostic integrated circuit housed within the power tool device, power from the external device, wherein the diagnostic integrated circuit includes a processing circuit separate from a processor of the electronic controller, a diagnostic sensor, and an external communication interface;
performing, by the diagnostic integrated circuit, a diagnostic test of the electronic controller; and
transmitting, by the diagnostic integrated circuit via the external communication interface, a test result of the diagnostic test of the electronic controller to the external device.

8. A power tool device, the power tool device comprising:
a device housing;
a power tool battery pack interface coupled to the device housing;
an electronic controller including a memory storing firmware and a processor configured to execute the firmware to cause the electronic controller to:
receive a request from an external device to perform a self-test;
in response to the request, perform the self-test;
record results corresponding to the self-test; and
export the results to the external device.

9. The power tool device of claim 8, wherein the request from the external device is received by the electronic controller via the power tool battery pack interface and wherein the results exported to the external device are transmitted by the electronic controller via the power tool battery pack interface.

10. The power tool device of claim 8, the power tool device further comprising:
a motor supported by the device housing and coupled to the electronic controller; and
a trigger coupled to the electronic controller, wherein the electronic controller is further configured to drive the motor in response to actuation of the trigger.

11. The power tool device of claim 8, further comprising:
a diagnostic integrated circuit housed by the device housing and comprising: a processing circuit separate from the processor of the electronic controller, a diagnostic sensor, and an external communication interface, wherein the diagnostic integrated circuit is configured to:
receive power from the external device;
perform, by the processing circuit, a diagnostic test of the electronic controller; and
transmit, by the processing circuit via the external communication interface, a test result of the diagnostic test of the electronic controller to the external device.

12. The power tool device of claim 11, further comprising:
a motor supported by the device housing; and
a switching network coupled to the electronic controller, wherein the electronic controller is configured to control the switching network to drive the motor,
wherein the diagnostic integrated circuit further comprises:
a service switching interface coupling the processing circuit to the switching network,
a power sensor configured to detect power at a power supply for the electronic controller,
a plurality of diagnostic sensors, and
a power input interface configured to receive the power from the external device.

13. The power tool device of claim 8, wherein performing the self-test comprises illuminating a light emitting diode (LED).

14. The power tool device of claim 8, wherein the power tool device is a motorized power tool is a drill-driver, an impact driver, a crimper, or a saw.

15. A power tool device, the power tool device comprising:
a device housing;
a power tool battery pack interface coupled to the device housing;
an electronic controller including a memory storing firmware and a processor configured to execute the firmware to cause the electronic controller to:
operate electronics of the power tool device;
a diagnostic integrated circuit housed by the device housing and comprising: a processing circuit separate from the processor of the electronic controller, a diagnostic sensor, and an external communication interface, wherein the diagnostic integrated circuit is configured to:
receive power from an external device;
perform, by the processing circuit, a diagnostic test of the electronic controller; and
transmit, by the processing circuit via the external communication interface, a test result of the diagnostic test of the electronic controller to the external device.

16. The power tool device of claim 15,
wherein the electronics include a motor and wherein, to operate the electronics of the power tool device, the electronic controller is configured to:
control a switching network to apply power from a power tool battery pack coupled to the power tool battery pack interface to the motor to drive the motor; and
wherein the diagnostic integrated circuit is offline and unpowered by the power tool battery pack when the switching network is controlled to apply power from the power tool battery pack to the motor and when the power tool battery pack is coupled to the power tool battery pack interface.

17. The power tool device of claim 15, further comprising:
a motor supported by the device housing; and
a switching network coupled to the electronic controller, wherein the electronic controller is configured to control the switching network to drive the motor,
wherein the diagnostic integrated circuit further comprises:
a service switching interface coupling the processing circuit to the switching network,
a power sensor configured to detect power at a power supply for the electronic controller,
a plurality of diagnostic sensors, and
a power input interface configured to receive the power from the external device.

18. The power tool device of claim 17, wherein the plurality of diagnostic sensors comprises at least one of: a power regulation sensor, a pressure sensor, an inductive position sensor, or an inertial measurement unit sensor.

19. The power tool device of claim 15, wherein the power tool device is a motorized power tool is a drill-driver, an impact driver, a crimper, or a saw.
